(19) United States
(12) Patent Application Publication
(10) Pub. No.: US 2023/0168569 A1
(43) Pub. Date: Jun. 1, 2023

(54) HEAT DIFFUSER, WAVELENGTH CONVERTER, LIGHT SOURCE APPARATUS, AND PROJECTOR

(71) Applicant: SEIKO EPSON CORPORATION, Tokyo (JP)

(72) Inventors: Kosuke TABAYASHI, Matsumoto-shi (JP); Norikazu KADOTANI, Azumino-shi (JP)

(21) Appl. No.: 17/993,177

(22) Filed: Nov. 23, 2022

(30) Foreign Application Priority Data
Nov. 26, 2021 (JP) 2021-191792

(51) Int. Cl. G03B 21/16; G02B 26/00; G03B 21/20; H05K 7/20

(52) U.S. Cl. CPC G03B 21/16; G02B 26/008; G03B 21/204; H05K 7/20318

(57) ABSTRACT

A heat diffuser according to an aspect of the present disclosure includes a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than that of copper. The inner surface of the housing compartment is covered with a coating layer. The coating layer is a resin coat containing any of alkyd resin, silicone resin, ethylene-chlorotrifluoroethylene copolymer resin, and tetrafluoroethylene-perfluoro alkyl vinyl ether copolymer resin. The heat from the heat receiver vaporizes the operating fluid in the liquid form, and the heat dissipation performed by the heat dissipater condenses the operating fluid.

The present application is based on, and claims priority from JP Application Serial Number 2021-191792, filed Nov. 26, 2021, the disclosure of which is hereby incorporated by reference herein in its entirety.

### BACKGROUND

### 1. Technical Field

The present disclosure relates to a heat diffuser, a wavelength converter, a light source apparatus, and a projector.

### 2. Related Art

A heat diffuser, such as a vapor chamber and a heat pipe, has been used as a cooler that cools a heat source. Such a heat diffusion apparatus has a configuration in which an operating fluid housed in a body portion is vaporized by heat received by a heat receiver, and the vaporized operating fluid is condensed in a heat dissipater into liquid.

In recent years, there is a demand in some cases for reduction in weight of the heat diffuser in accordance with a request for reduction in weight of an apparatus that incorporates the heat diffuser. The body portion of the heat diffuser has been made of a metal material that excels in thermal conductivity, but from the viewpoint of the reduction in weight, materials having low specific gravity, such as aluminum, are used in some cases among metal materials. Furthermore, to improve the cooling performance of the heat diffuser, water, the latent heat of vaporization of which is greater than that of chlorofluorocarbon or any other refrigerant, is used in some cases as the operating fluid. In view of such circumstances, to configure a heat diffuser that is lightweight and excels in cooling efficiency, it is conceivable to combine water as the operating fluid with the body portion made of aluminum.

Aluminum reacts in the air and an oxide coating is formed thereon. Therefore, when aluminum on which an oxide coating has been formed is left in water, microscopic holes are created in the oxide coating and trigger corrosion of the aluminum, resulting in deterioration of the body portion. The corrosion also produces non-condensable hydrogen gas in the body of the diffuser, and the hydrogen gas lowers the degree of vacuum in the body of the diffuser, which prevents the vaporization of the water and therefore reduces the cooling performance of the heat diffuser.

For example, in the heat diffuser disclosed in JP-A-60-191192, the corrosion of a body portion that houses water as the operating fluid is suppressed by formation of a boehrmite treated coating on the surface of aluminum that forms the body portion.

In the heat diffuser disclosed in JP-A-2010-60206, the hydrogen gas produced by the corrosion is oxidized into water by a hydrogen remover fitted at a plurality of locations into the inner surface of the body portion that houses water as the operating fluid.

In the heat diffuser disclosed in JP-A-11-304381, the corrosion of aluminum that forms a body portion that houses water as the operating fluid is suppressed by formation of a coating layer and a porous layer that covers the coating layer on the surface of the aluminum.

In the heat diffuser disclosed in JP-A-60-191192, however, the boehmite treated film, which is typically a thin film having a thickness ranging from 0.1 to 2 μm, is readily scratched, resulting in a problem of corrosion of the aluminum exposed via the scratches.

In the heat diffuser disclosed in JP-A-2010-60206, an oxide coating is formed on the aluminum surface of a portion of the inner surface of the body portion, the portion where no hydrogen remover is provided, resulting in a problem of corrosion of the aluminum triggered by microscopic holes produced in the oxide coating.

In the heat diffuser disclosed in JP-A-11-304381, the coating layer and the porous layer are produced by sintering fine copper particle powder, resulting in a problem of corrosion of the aluminum via the pores produced during the sintering.

It has therefore been difficult for the heat diffusers disclosed in JP-A-60-191192, JP-A-2010-60206, and JP-A-11-304381 to achieve both weight reduction and improved cooling efficiency.

### SUMMARY

To solve the problem described above, according to a first aspect of the present disclosure, there is provided a heat diffuser including a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than specific gravity of copper. An inner surface of the housing compartment is covered with a coating layer. The coating layer is a resin coat containing any of alkyd resin, silicone resin, ethylene-chlorotrifluoroethylene copolymer resin, and tetrafluoroethylene-perfluoro alkyl vinyl ether copolymer resin. The heat from the heat receiver vaporizes the operating fluid in a liquid form, and the heat dissipation performed by the heat dissipater condenses the operating fluid.

According to a second aspect of the present disclosure, there is provided a wavelength converter including a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than specific gravity of copper. An inner surface of the housing compartment is covered with a coating layer. At least a surface of the coating layer is formed of a plated layer made of a metal having an ionization tendency smaller than an ionization tendency of hydrogen. The heat from the heat receiver vaporizes the operating fluid in a liquid form, and the heat dissipation performed by the heat dissipater condenses the operating fluid.

According to a third aspect of the present disclosure, there is provided a light source apparatus including a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than specific gravity of copper. An inner surface of the housing compartment is covered with a coating layer. The coating layer is a glass coating containing silicon dioxide. The heat from the heat receiver vaporizes the operating fluid in a liquid form, and the heat dissipation performed by the heat dissipater condenses the operating fluid.

According to a fourth aspect of the present disclosure, there is provided a wavelength converter including a phosphor wheel including a wheel substrate, a phosphor provided at a first surface of the wheel substrate, and a heat dissipating member provided at a second surface of the wheel substrate, the surface opposite from the first surface, and a vapor chamber that is formed of the heat diffuser according to the aspect described above and cools the phosphor. The vapor chamber is so provided as to be integrated with the wheel substrate or provided between the wheel substrate and the heat dissipating member.

According to a fifth aspect of the present disclosure, there is provided a light source apparatus including a light source and a vapor chamber that cools the light source, and the vapor chamber is the heat diffuser according to the aspect described above.

According to a sixth aspect of the present disclosure, there is provided a light source apparatus including a light source and a heat pipe that cools the light source, and the heat pipe is the heat diffuser according to the aspect described above.

According to a seventh aspect of the present disclosure, there is provided a light source apparatus including the wavelength converter according to the second aspect and a light source that outputs excitation light to the phosphor wheel of the wavelength converter.

According to an eighth aspect of the present disclosure, there is provided a projector including the light source apparatus according to the aspect described above, a light modulator that modulates light from the light source apparatus in accordance with image information to form image light, and a projection optical apparatus that projects the image light.

### BRIEF DESCRIPTION OF THE DRAWINGS

FIG. 1 is a schematic configuration diagram of a projector according to a first embodiment.

FIG. 2 is a schematic configuration diagram showing a light source apparatus according to the first embodiment.

FIG. 3 is a cross-sectional view showing the configurations of key parts of a first light source.

FIG. 4 is a cross-sectional view showing the configurations of key parts of a coating layer according to a first variation.

FIG. 5A is a cross-sectional view showing a schematic configuration of the coating layer according to a second variation.

FIG. 5B is a cross-sectional view showing a schematic configuration of the coating layer according to a third variation.

FIG. 6 shows the configurations of key parts of a vapor chamber in a second embodiment.

FIG. 7 is a cross-sectional view showing a schematic configuration of the coating layer according to a fourth variation.

FIG. 8A is a cross-sectional view showing a schematic configuration of the coating layer according to a fifth variation.

FIG. 8B is a cross-sectional view showing a schematic configuration of the coating layer according to a sixth variation.

FIG. 9 shows the configurations of key parts of the vapor chamber according to a third embodiment.

FIG. 10 shows the configurations of key parts of the vapor chamber according to a fourth embodiment.

FIG. 11 is a cross-sectional view showing the configurations of key parts of a wavelength converter according to a fifth embodiment.

FIG. 12 is a cross-sectional view showing the configurations of key parts of the wavelength converter according to a seventh variation.

FIG. 13 is a cross-sectional view showing a schematic configuration of a heat pipe according to a sixth embodiment.

### DESCRIPTION OF EXEMPLARY EMBODIMENTS

Embodiments of the present disclosure will be described below in detail with reference to the drawings.

In the drawings used in the description below, a characteristic portion is magnified for convenience in some cases for clarity of the characteristic thereof, and the dimension ratio and other factors of each component are therefore not always equal to actual values.

### First Embodiment

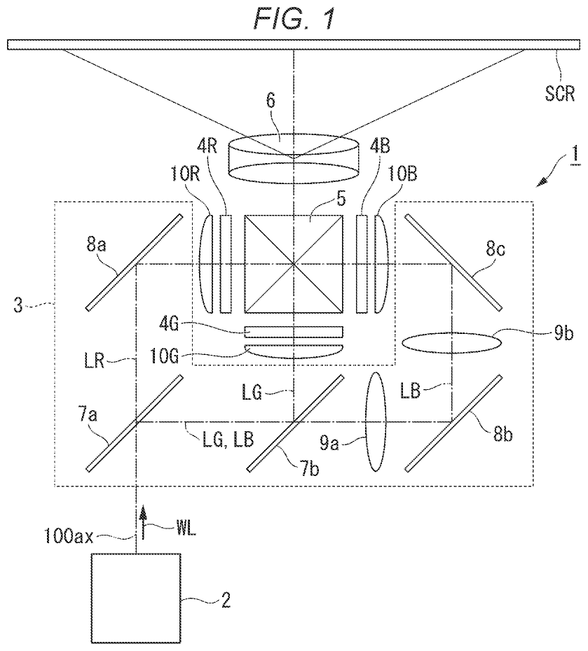

FIG. 1 is a schematic configuration diagram of a projector according to the present embodiment.

A projector 1 according to the present embodiment is a projection-type image display apparatus that displays video images on a screen SCR, as shown in FIG. 1. The projector 1 includes a light source apparatus 2, a color separation system 3, light modulators 4R, 4G, and 4B, a light combining system 5, and a projection optical apparatus 6.

The light source apparatus 2 outputs white illumination light WL toward the color separation system 3. The configuration of the light source apparatus 2 will be described later.

The color separation system 3 separates the illumination light WL outputted from the light source apparatus 2 into red light LR, green light LG, and blue light LB. The color separation system 3 includes a first dichroic mirror 7a, a second dichroic mirror 7b, a first total reflection mirror 8a, a second total reflection mirror 8b, a third total reflection mirror 8c, a first relay lens 9a, and a second relay lens 9b.

The first dichroic mirror 7a separates the illumination light WL from the light source apparatus 2 into the red light LR and light containing the green light LG and the blue light LB. The first dichroic mirror 7a transmits the red light LR and reflects the light containing the green light LG and the blue light LB. On the other hand, the second dichroic mirror 7b reflects the green light LG and transmits the blue light LB. The second dichroic mirror 7b thus separates the light incident from the first dichroic mirror 7a into the green light LG and the blue light LB.

The first total reflection mirror 8a is disposed in the optical path of the red light LR and reflects the red light LR having passed through the first dichroic mirror 7a toward the light modulator 4R. On the other hand, the second total reflection mirror 8b and the third total reflection mirror 8c are disposed in the optical path of the blue light LB and guide the blue light LB having passed through the second dichroic mirror 7b to the light modulator 4B. The green light LG is reflected off the second dichroic mirror 7b toward the light modulator 4G.

The first relay lens 9a and the second relay lens 9b are disposed in the optical path of the blue light LB on the light exiting side of the second total reflection mirror 8b. The first relay lens 9a and the second relay lens 9b compensate for optical loss of the blue light LB resulting from the fact that the optical path length of the blue light LB is longer than the optical path lengths of the red light LR and the green light LG.

The light modulator 4R modulates the red light LR in accordance with image information to form image light corresponding to the red light LR. The light modulator 4G modulates the green light LG in accordance with image information to form image light corresponding to the green light LG. The light modulator 4B modulates the blue light LB in accordance with image information to form image light corresponding to the blue light LB.

The light modulators 4R, 4G, and 4B are each, for example, a transmissive liquid crystal panel. Polarizers that are not shown are disposed on the light incident and exiting sides of each of the liquid crystal panels.

A field lens 10R is disposed on the light incident side of the light modulator 4R. The field lens 10R parallelizes the red light LR to be incident on the light modulator 4R. A field lens 10G is disposed on the light incident side of the light modulator 4G. The field lens 10G parallelizes the green light LG to be incident on the light modulator 4G. A field lens 10B is disposed on the light incident side of the light modulator 4B. The field lens 10B parallelizes the blue light LB to be incident on the light modulator 4B.

The image light outputted from the light modulator 4R, the image light outputted from the light modulator 4G, and the image light outputted from the light modulator 4B enter the light combing system 5. The light combining system 5 combines the image light corresponding to the red light LR, the image light corresponding to the green light LG, and the image light corresponding to the blue light LB with one another and outputs the combined image light toward the projection optical apparatus 6. The light combining system 5 is formed, for example, of a cross dichroic prism.

The projection optical apparatus 6 includes a plurality of projection lenses. The projection optical apparatus 6 magnifies the combined image light from the light combining system 5 and projects the magnified image light toward the screen SCR. Magnified video images are thus displayed on the screen SCR.

The configuration of the light source apparatus 2 will be described below.

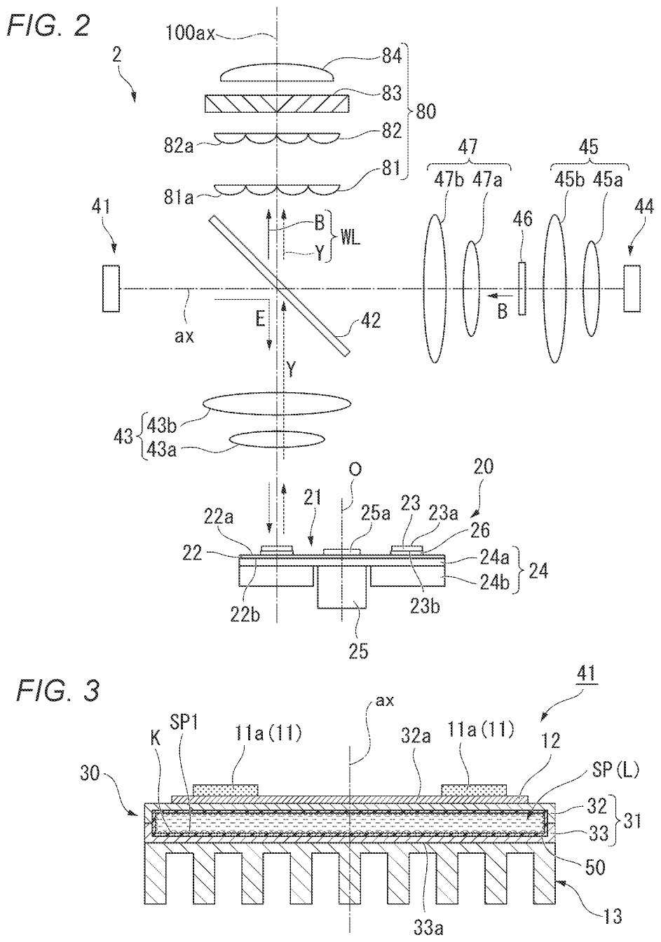

FIG. 2 is a schematic configuration diagram showing the light source apparatus 2 according to the present embodiment.

The light source apparatus 2 includes a first light source 41, which is a light source, a dichroic mirror 42, a collimation and condenser system 43, a wavelength converter 20, a second light source 44, a condenser system 45, a diffuser 46, and a collimation system 47, as shown in FIG. 2.

The first light source 41 outputs blue excitation light E formed of laser light toward the dichroic mirror 42. The configuration of the first light source 41 will be described later.

The dichroic mirror 42 is disposed in the optical path between the first light source 41 and the collimation and condenser system 43 and oriented so as to intersect with an optical axis ax of the first light source 41 and an illumination optical axis 100ax at an angle of 45°. The dichroic mirror 42 reflects a blue light component and transmits a red light component and a green light component. The dichroic mirror 42 therefore reflects the excitation light E and blue light B, the latter of which will be described later, and transmits yellow fluorescence Y.

The collimation and condenser system 43 collects the excitation light E reflected off the dichroic mirror 42 and causes the collected excitation light E to enter the wavelength converter 20 and also substantially parallelizes the fluorescence Y, which will be described later and emitted from the wavelength converter 20. The collimation and condenser system 43 includes a first lens 43a and a second lens 43b. The first lens 43a and the second lens 43b are each formed of a convex lens.

The wavelength converter 20 includes a phosphor wheel 21 and a rotation driver 25. The phosphor wheel 21 includes a wheel substrate 22, a phosphor 23, and a heat dissipating member 24. The rotation driver 25 is formed of a motor apparatus. The rotation driver 25 includes a rotation support 25a, which is rotatable around a center axis O, which is an imaginary axis. The phosphor wheel 21 is fixed to the rotation driver 25 via the rotation support 25a and therefore rotates around the center axis O.

The wheel substrate 22 has a first surface 22a and a second surface 22b opposite from the first surface 22a. The wheel substrate 22 is formed of an annular plate made of metal that excels in heat dissipation, for example, aluminum and copper. That is, the wheel substrate 22 has thermal conductivity in the present embodiment.

The phosphor 23 is formed in an annular shape around the center axis O on the first surface 22a of the wheel substrate 22. In the present embodiment, the phosphor 23 is provided in a ring shape around the center axis O.

The phosphor 23 is excited by the excitation light E incident via an upper surface 23a and emits the fluorescence Y, which is yellow light containing red light and green light, via the upper surface 23a, as shown in FIG. 2. The phosphor 23 is made, for example, of YAG:Ce, which is garnet crystal (YAG) expressed by Y₃Al₅O₁₂ to which cerium ions, Ce³⁺, for example, are added. The phosphor 23 may contain suitable scatterers that are not shown.

In the present embodiment, a reflection member 26 is provided between a rear surface 23b of the phosphor 23 and the first surface 22a of the wheel substrate 22. The reflection member 26 reflects light that exits via the rear surface 23b of the phosphor 23 toward the upper surface 23a.

The heat dissipating member 24 is provided on the side facing the second surface 22b of the wheel substrate 22. The heat dissipating member 24 includes a base section 24a, which is bonded to the second surface 22b of the wheel substrate 22, and a plurality of heat dissipating fins 24b provided at the base section 24a. The base section 24a is formed of a circular plate made of metal that excels in heat dissipation, for example, aluminum and copper. The base section 24a has the same external shape as that of the wheel substrate 22.

Based on the configuration described above, the wavelength converter 20 according to the present embodiment, in which the excitation light E from the first light source 41 is incident on the upper surface 23a of the phosphor 23, which is rotated by the rotation driver 25, emits the fluorescence Y. Heat generated by the phosphor 23 during the emission of the fluorescence Y is transferred through the wheel substrate 22 to the base section 24a of the heat dissipating member 24. The heat transferred to the base section 24a is dissipated via the heat dissipating fins 24b.

When the temperature of the phosphor 23 becomes too high, the efficiency at which the excitation light E is converted in terms of wavelength into the fluorescence Y may decrease and the amount of emitted fluorescence Y may therefore decrease. The wavelength converter 20 according to the present embodiment can suppress an increase in the temperature of the phosphor 23 by rotating the phosphor wheel 21 to change the position where the excitation light E is incident on the phosphor 23, and can further efficiently cool the phosphor 23 via the heat dissipating member 24 to suppress a decrease in the fluorescence conversion efficiency resulting from an increase in the temperature of the phosphor 23. The wavelength converter 20 can therefore generate bright fluorescence Y.

The second light source 44 outputs the blue light B formed of laser light that belongs to the same wavelength band as that to which the excitation light E outputted from the first light source 41 belongs. The second light source 44 may be formed of one semiconductor laser or a plurality of semiconductor lasers.

The condenser system 45 includes a first lens 45a and a second lens 45b. The condenser system 45 collects the blue light B outputted from the second light source 44 on or in the vicinity of a diffusion surface of the diffuser 46. The first lens 45a and the second lens 45b are each formed of a convex lens.

The diffuser 46 diffuses the blue light B outputted from the second light source 44 to produce blue light B having a light orientation distribution close to the light orientation distribution of the fluorescence Y emitted from the wavelength converter 20. The diffuser 46 can be formed, for example, of a ground glass plate made of optical glass.

The collimation system 47 includes a first lens 47a and a second lens 47b. The collimation system 47 substantially parallelizes the light having exited out of the diffuser 46. The first lens 47a and the second lens 47b are each formed of a convex lens.

The blue light B outputted from the second light source 44 is reflected off the dichroic mirror 42 and combined with the fluorescence Y having been emitted from the wavelength converter 20 and having passed through the dichroic mirror 42 into the white illumination light WL. The illumination light WL enters a uniform illumination system 80.

The uniform illumination system 80 includes a first lens array 81, a second lens array 82, a polarization converter 83, and a superimposing lens 84.

The first lens array 81 includes a plurality of first lenses 81a for dividing the illumination light WL from the light source apparatus 2 into a plurality of sub-luminous fluxes. The plurality of first lenses 81a are arranged in a matrix in a plane perpendicular to the illumination optical axis 100ax.

The second lens array 82 includes a plurality of second lenses 82a corresponding to the plurality of first lenses 81a in the first lens array 81. The plurality of second lenses 82a are arranged in a matrix in a plane perpendicular to the illumination optical axis 100ax.

The second lens array 82 along with the superimposing lens 84 brings images of the first lenses 81a of the first lens array 81 into focus in the vicinity of an image formation region of each of the light modulators 4R, 4G, and 4B.

The polarization converter 83 converts the light having exited out of the second lens array 82 into one kind of linearly polarized light. The polarization converter 83 includes, for example, polarization separation films and retardation films, none of which is shown.

The superimposing lens 84 collects the sub-luminous fluxes having exited out of the polarization converter 83 and superimposes the collected sub-luminous fluxes on one another in the vicinity of the image formation region of each of the light modulators 4R, 4G, and 4B.

The configuration of the first light source 41 will be subsequently described. FIG. 3 is a cross-sectional view showing the configurations of key parts of the first light source 41.

The first light source 41 includes a light emitter 11 including a plurality of light emitting units 11a, a mounting substrate 12, a heat dissipating member 13, and a vapor chamber 30, which is a heat diffuser, as shown in FIG. 3. In the present embodiment, the plurality of light emitting units 11a are arranged two-dimensionally along a plane perpendicular to the optical axis ax of the first light source 41. The plurality of light emitting units 11a are mounted on the mounting substrate 12. In the present embodiment, the plurality of light emitting units 11a are mounted on the single mounting substrate 12 by way of example, and the mounting substrate 12 may be divided into a plurality of portions.

The light emitting units 11a each include, for example, a plurality of laser devices that each output blue laser light having a peak wavelength that falls within a range from 380 to 495 nm, and a plurality of collimator lenses that are provided in correspondence with the laser devices and each collimate the blue laser light from the corresponding laser device. The plurality of light emitting units 11a thus each output a parallelized blue laser light.

Based on the configuration described above, the first light source 41 in the present embodiment outputs the excitation light E formed of a parallelized blue laser luminous flux from the light emitter 11 toward the dichroic mirror 42.

The number of light emitting units 11a is set as appropriate in accordance with the required power of the excitation light E from the first light source 41. For example, in a case where the excitation light E does not need to have large power, only one light emitting unit 11a may be provided.

The vapor chamber 30 is an apparatus that cools the first light source 41 including the light emitter 11 by diffusing the heat from the light emitter 11, which is heated when outputting the excitation light E formed of laser light.

The vapor chamber 30 includes a body section 31. The body section 31 includes a heat receiver 32a, which receives the heat from the light emitter 11, which is the heat source, a heat dissipater 33a, which dissipates the heat received by the heat receiver 32a, and a housing compartment SP, which houses and seals an operating fluid L. The body section 31 is the combination of a heat receiving plate 32 and a heat dissipating plate 33. The heat receiving plate 32 and the heat dissipating plate 33 are each a flat-plate-shaped member having a depression corresponding to the housing compartment SP.

The mounting substrate 12 of the first light source 41 is provided at the heat receiving plate 32 of the vapor chamber 30, and the heat dissipating member 13 of the first light source 41 is provided at the heat dissipating plate 33 of the vapor chamber 30.

That is, the heat receiving plate 32 is thermally coupled to the mounting substrate 12 of the light emitter 11. The term “thermally coupled” used herein means that the light emitter 11 and the heat receiving plate 32 are so coupled to each other that the heat from the light emitter 11 is transferable toward the heat receiving plate 32 via the mounting substrate 12. The light emitter 11 and the heat receiving plate 32 may be in direct contact with each other or may be in indirect contact with each other with a heat conducting member sandwiched therebetween.

The heat receiver 32a is provided at a surface of the heat receiving plate 32, the surface opposite from the housing compartment SP. The heat receiver 32a receives the heat from the light emitter 11 transferred via the mounting substrate 12 and transforms the operating fluid L from liquid into gas.

The heat dissipater 33a is provided at a surface of the heat dissipating plate 33, the surface opposite from the housing compartment SP. The heat dissipater 33a dissipates the heat of the gaseous operating fluid L flowing in the housing compartment SP to condense the operating fluid L into liquid. The heat dissipating member 13 is provided at a portion of the outer surface of the heat dissipating plate 33, the portion corresponding to the heat dissipater 33a. The heat dissipating member 13 is formed of a heat sink including a plurality of plate-shape heat dissipating fins 13a.

The body section of the vapor chamber has been made of a metal material that excels in thermal conductivity, such as copper and aluminum. The specific gravity of copper, which is 8.96 g/cm³, is much greater than that of aluminum, which is 2.70 g/cm³. Therefore, to reduce the weight of the vapor chamber, the body section needs to be made of a metal material having specific gravity smaller than that of copper.

To increase the cooling efficiency of the vapor chamber, water having large latent heat of evaporation needs to be used as the operating fluid. It is therefore conceivable to house water as the operating fluid in the body section made of aluminum so as to concurrently reduce the weight of the vapor chamber and improve the cooling efficiency.

As Comparative Example, a description will now be made of a vapor chamber in which water is housed as the operating fluid in a body section made of aluminum having specific gravity lower than that of copper. In the vapor chamber in Comparative Example, the aluminum exposed at the inner surface of the body section, which forms the housing space, is in contact with the water, which is the operating fluid.

In the following description, the water in the liquid state as the operating fluid is called “water”, and the water in the gaseous state as the operating fluid is called “water vapor”.

In the vapor chamber in Comparative Example, aluminum, of which the body section is made, has an ionization tendency greater than that of hydrogen, and therefore causes reduction in strength of the body section when aluminum reacts with the water or water vapor and corrodes. Furthermore, non-condensable hydrogen gas is produced in the body section as a result of the corrosion. In general, the temperature at which the operating fluid vaporizes is set low by depressurizing the body section of the vapor chamber. However, when the non-condensable hydrogen gas is produced, the degree of vacuum in the body section decreases, that is, the degree of the depressurization decreases, which lowers the efficiency at which the operating fluid vaporizes, resulting in reduced cooling performance.

The vapor chamber 30 in the present embodiment allows suppression of the production of the hydrogen gas even when the body section 31 is made of a metal material having specific gravity smaller than that of copper to reduce the weight of the light source apparatus 2, and when water is used as the operating fluid to increase the cooling efficiency.

In the present specification, the water includes what is called ordinary water as well as pure water containing few impurities. Ordinary water contains a larger amount of impurities and is therefore more electrically conductive than pure water, and is hence more likely to cause corrosion. The vapor chamber 30 in the present embodiment can suppress the production of hydrogen gas associated with the corrosion caused by ordinary water, which is more likely to cause corrosion than pure water. The vapor chamber 30 in the present embodiment can therefore similarly suppress the production of hydrogen gas associated with the corrosion caused by pure water.

In the vapor chamber 30 in the present embodiment, the heat receiving plate 32 and the heat dissipating plate 33, which form the body section 31, are made of a metal material having specific gravity smaller than that of copper. Examples of the metal material having specific gravity smaller than that of copper, of which the body section 31 is made, may include SUS having a specific gravity of 7.9 g/cm³, titanium having a specific gravity of 4.5 g/cm³, and magnesium having a specific gravity of 1.7 g/cm³ as well as aluminum. In the present embodiment, the body section 31 is made of aluminum.

The vapor chamber 30 in the present embodiment includes a coating layer 50, which covers an inner surface SP1 of the housing compartment SP.

The coating layer 50 is a resin coat containing any of the following resins: alkyd resin; silicone resin; ethylene-chlorotrifluoroethylene copolymer resin; and tetrafluoroethylene-perfluoro alkyl vinyl ether copolymer resin. In the present embodiment, the thickness of the coating layer 50 is set at a value ranging, for example, from 300 to 400 μm.

The resin coat that forms the coating layer 50 can be readily formed by applying paint made of any of the resin materials described above to which a solvent, an additive, and pigment are added onto the inner surface SP1 of the housing compartment SP and drying the paint. In the present embodiment, xylene or toluene, for example, is desirably used as the solvent. Using zinc phosphate as the additive allows increased adhesion between a ground surface, which is the inner surface SP1 of the housing compartment SP, and the coating layer 50, suppressing separation of the coating layer 50 from the inner surface SP1.

Alkyd resin is classified into polyester resin and is an ester compound resulting from co-polycondensation that proceeds by dehydration condensation of polyhydric alcohol modified with fatty acid and polybasic acid or acid anhydride. Alkyd resin excels in adhesion to metal and therefore has corrosion protection improving performance. Alkyd resin also excels in mechanical properties, such as bending resistance, impact resistance, and abrasion resistance. Alkyd resin is resistant to heat ranging from 100° C. to 200° C.

In the present embodiment, the silicone resin is preferably any of pure silicone resin, modified silicone resin, and inorganic-filler-added silicone resin.

For example, pure silicone resin is a siloxane polymer having methyl and phenyl groups and is resistant to heat ranging from 200° C. to 250° C.

The modified silicone resin is rubber-like silicone resin modified with alkyd resin, polyester resin, epoxy resin, acrylic resin, or any other suitable resin, and is resistant to heat ranging from 150° C. to 200° C.

The inorganic-filler-added silicone resin is silicone resin to which heat-resistant pigment, aluminum powder, graphite, ceramic powder, or any other suitable substance is added and is resistant to heat ranging from 300° C. to 650° C.

A resin containing a metal oxide may be used as the aforementioned silicone resin that forms the coating layer 50. Using silicone resin containing a metal oxide as described above allows the coating layer 50 to be resistant to heat up to 400° C.

Ethylene-chlorotrifluoroethylene copolymer resin (ECTFE) is fluorocarbon resin resistant to heat ranging from 130° C. to 150° C. Tetrafluoroethylene-perfluoro alkyl vinyl ether copolymer resin (PFA) is fluorocarbon resin resistant to heat of about 260° C.

In the present embodiment, the resin material of which the coating layer 50 is made is selected as appropriate in accordance with the required heat resistance. The vapor chamber 30 in the present embodiment is used to cool the light emitter 11 and therefore only needs to be resistant to heat of at least 100° C.

The vapor chamber 30 in the present embodiment has a wick structure K provided in the housing compartment SP. The wick structure K is provided at least on the coating layer 50 that covers the inner surface of the heat receiving plate 32. At least part of the wick structure K may be provided on the coating layer 50 that covers the inner surface of the heat dissipating plate 33. The wick structure K may include a plurality of columnar elements. For example, the plurality of columnar elements are disposed in the housing compartment SP so as to be in contact with the coating layer 50 that covers the inner surface of the heat receiving plate 32 and the coating layer 50 that covers the inner surface of the heat dissipating plate 33.

The wick structure K is permeated with water, which is the operating fluid L sealed in the depressurized housing compartment SP. The wick structure K is a finely woven structure, which can produce a capillary force. The heat receiver 32a supplies a portion of the heat receiving plate 32, the portion being in contact with the light emitter 11, with the water with the aid of the capillary force produced by the wick structure K.

In the vapor chamber 30 in the present embodiment, the heat receiver 32a vaporizes the water having permeated the wick structure K with the aid of the heat transferred from the light emitter 11. The water vapor vaporized by the heat receiver 32a flows along a channel formed in the housing compartment SP and moves to the heat dissipater 33a of the heat dissipating plate 33, which is located on a side of the heat receiving plate 32, the side opposite from the mounting substrate 12. The heat dissipater 33a efficiently dissipates the heat of the water vapor out of the first light source 41 via the heat dissipating fins 13a of the heat dissipating member 13.

The water condensed by the heat dissipater 33a permeates the wick structure K provided in the housing compartment SP, is supplied to the heat receiver 32a by the capillary force produced by the wick structure K, and is vaporized again by the heat receiver 32a. The vapor chamber 30 thus diffuses the heat of the light emitter 11 from the heat receiver 32a to the heat dissipater 33a to cool the light emitter 11.

The vapor chamber 30 in the present embodiment, in which the body section 31 is made of aluminum, which has specific gravity smaller than that of copper, is lighter at least than a vapor chamber made of copper. In addition, using water, the latent heat of vaporization of which is large, as the operating fluid, can provide high cooling performance. Furthermore, the operating fluid formed of water does not cause an adverse effect on the environment, such as the greenhouse effect, unlike chlorofluorocarbon.

In the present embodiment, the inner surface SP1 of the housing compartment SP is covered with the coating layer 50, so that the water housed in the housing compartment SP is not in direct contact with the aluminum of which the housing compartment SP is made, whereby the production of hydrogen gas in the housing compartment SP can be suppressed. The coating layer 50 is a resin coat and can therefore be readily thick. Therefore, even when the coating layer 50 is scratched, the inner aluminum surface SP1 of the housing compartment SP is unlikely to be exposed, whereby production of the hydrogen gas can be suppressed. The problem of a decrease in the strength of the aluminum of which the body section 31 is made due to corrosion can therefore be suppressed. Furthermore, since non-condensable hydrogen gas is not produced in the housing compartment SP, the decrease in cooling performance due to the hydrogen gas production can be suppressed.

In the present embodiment, the case where the body section 31 is made of aluminum is presented by way of example, and aforementioned SUS, titanium, and magnesium, and other metal materials having specific gravity smaller than that of copper have an ionization tendency greater than that of hydrogen as aluminum does, and can therefore undesirably produce hydrogen gas when the operating fluid is water. Therefore, when the body section 31 is made of SUS, titanium, or magnesium, which has specific gravity smaller than that of copper, providing the coating layer 50 can similarly suppress the hydrogen gas production.

The vapor chamber 30 in the present embodiment therefore allows suppression of the production of hydrogen gas even when the body section 31 is made of a metal material having specific gravity smaller than that of copper to reduce the weight of the entire apparatus, and when water is used as the operating fluid. That is, according to the vapor chamber 30 in the present embodiment, a heat diffuser that achieves both weight reduction and improved cooling efficiency can be provided.

The light source apparatus 2 according to the present embodiment, which includes the vapor chamber 30, which achieves both weight reduction and improved cooling efficiency, can be a lightweight light source apparatus that dissipates a suppressed amount of heat out of the apparatus. The reliability of the projector 1 according to the present embodiment can be improved because optical members around the light source apparatus 2 are unlikely to be affected by the heat dissipated from the light source apparatus 2. Furthermore, since the projector 1 according to the present embodiment includes the lightweight light source apparatus 2, an increase in the weight of the projector itself can be suppressed.

### First Variation

In the vapor chamber 30 in the first embodiment, the coating layer 50 is formed of a monolayer resin coat, and the coating layer may instead have a multilayer structure in which a plurality of resin coats are laminated on each other. A coating layer having the multilayer structure will be described below as a first variation.

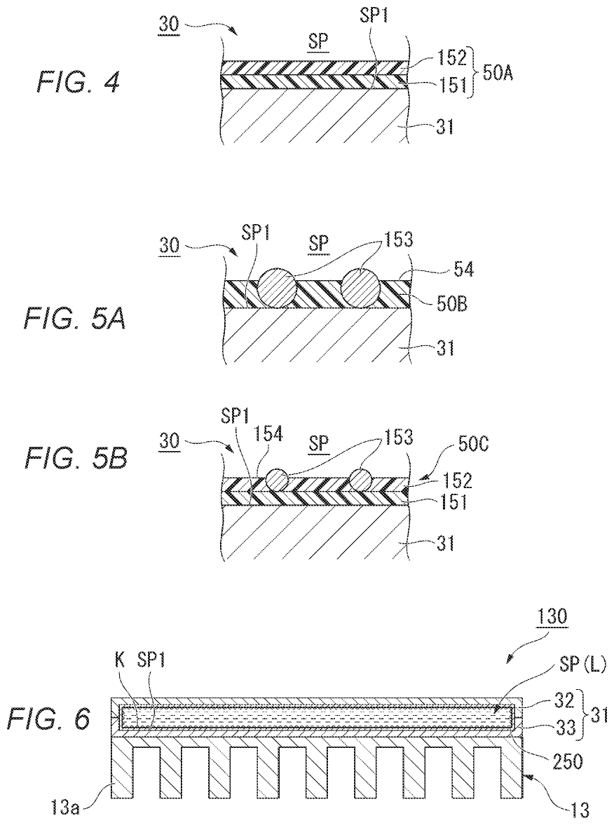

FIG. 4 is a cross-sectional view showing the configurations of key parts of a coating layer 50A according to the first variation.

The coating layer 50A according to the present variation has a laminated structure including a first resin coat 151 and a second resin coat 152, as shown in FIG. 4. The second resin coat 152 is laminated on the first resin coat 151.

The first resin coat 151 and the second resin coat 152 may be made of the same resin material or different resin materials.

For example, when the materials of the first resin coat 151 and the second resin coat 152 are ethylene-chlorotrifluoroethylene copolymer resin (ECTFE) and tetrafluoroethylene-perfluoro alkyl vinyl ether copolymer resin (PFA), respectively, it is preferable that ECTFE is used as the first resin coat 151, which forms the inner-side portion of the coating layer 50A, and that PFA, which excels in heat resistance by a greater degree, is used as the second resin coat 152, which forms the outer-side portion of the coating layer 50A.

The coating layer 50A according to the present variation, which employs the laminated structure to suppress the thickness of each of the resin coats 151 and 152 to a value between 20 and 50 μm, can still achieve scratch resistance comparable to that of the coating layer 50 having the monolayer structure having the thickness of 300 μm.

The number of laminated resin coats in the coating layer 50A described above is not limited to two, and three or more resin coats may be laminated on each other.

### Second Variation

In the vapor chamber 30 in the first embodiment, a plurality of metal particles may be incorporated in the resin coat that forms the coating layer 50. A coating layer in which metal particles are incorporated in the resin coat will be described below as a second variation.

FIG. 5A is a cross-sectional view showing a schematic configuration of a coating layer 50B according to the second variation.

A plurality of particles 153 are incorporated in the coating layer 50B according to the present variation, as shown in FIG. 5A. The plurality of particles 153 are, for example, metal oxide particles. In the present embodiment, the plurality of particles 153 are titania particles, that is, titanium oxide particles.

The particle diameter of the plurality of particles 153 is greater than the thickness of the coating layer 50B. The plurality of particles 153 are therefore provided so as to be exposed via a surface 54 of the coating layer 50B. The plurality of particles 153 can therefore produce a capillary force in the coating layer 50B. That is, the coating layer 50B according to the present variation, which satisfactorily holds the water, which is the operating fluid, with the aid of the capillary force, can along with the wick structure K shown in FIG. 3 or in place of the wick structure K facilitate circulation of the operating fluid in the housing compartment SP.

In the present variation, the titania particles, which form the plurality of particles 153, form a passive coating at the surface of the coating layer 50B. The titania particles exposed via the surface 54 of the coating layer 50B can therefore perform a self-repairing function of repairing scratches produced at the surface 54 of the coating layer 50B. That is, the coating layer 50B according to the present variation, which can self-repair scratches produced at the surface 54, can further enhance the corrosion suppression function by suppressing exposure of the aluminum surface of the body section 31 triggered by the scratches produced at the surface 54. The coating layer 50B according to the present variation, in which the inner surface SP1 of the housing compartment SP is stably covered for a long period of time, can therefore provide a vapor chamber 30 that excels in durability.

### Third Variation

The coating layer 50B according to the second variation has been described with reference to the case where the coating layer 50B has the monolayer structure, and the coating layer 50B may instead have a multilayer structure, such as that in the first variation described above. A case where metal particles are incorporated in a coating layer having a multilayer structure will be described below as a third variation.

FIG. 5B is a cross-sectional view showing a schematic configuration of a coating layer 50C according to the third variation.

The coating layer 50C includes a laminated structure including a first resin coat 151 and a second resin coat 152 laminated on the first resin coat 151, and a plurality of particles 153 are incorporated in the coating layer 50C, as shown in FIG. 5B. The plurality of particles 153 are incorporated in the second resin coat 152, which forms the outer-side portion of the coating layer 50C. The particle diameter of the plurality of particles 153 is greater than the thickness of the second resin coat 152. The plurality of particles 153 are therefore provided so as to be exposed via the surface of the coating layer 50C, that is, a surface 154 of the second resin coat 152.

The coating layer 50C according to the present variation has scratch resistance comparable to that of the coating layer 50B having the monolayer structure while reducing the overall thickness by employing the laminated structure and can facilitate the circulation of the operating fluid by producing the capillary force.

The number of laminated resin coats in the coating layer 50C described above is not limited to two, and three or more resin coats may be laminated on each other.

### Second Embodiment

The vapor chamber according to a second embodiment will be subsequently described. The difference between the present embodiment and the first embodiment is that the coating layer in the vapor chamber is formed of a plated metal in place of a resin coat. In the following description, configurations and members common to those in the first embodiment have the same reference characters and will not be described in detail.

FIG. 6 shows the configurations of key parts of a vapor chamber 130 in the second embodiment.

The vapor chamber 130 in the present embodiment includes a coating layer 250, which covers the inner surface SP1 of the housing compartment SP of the body section 31 made of aluminum having specific gravity smaller than that of copper, as shown in FIG. 6. The coating layer 250 in the present embodiment is formed of a plated metal layer made of a metal having an ionization tendency smaller than that of hydrogen.

The vapor chamber 130 in the present embodiment is used to cool, for example, the first light source 41 of the light source apparatus 2, as in the first embodiment.

The coating layer 250 in the present embodiment is formed of a monolayer plated layer. Examples of the metal material of which the plated layer, which forms the coating layer 250, is made include copper, silver, and gold. The coating layer 250 in the present embodiment is formed of a plated metal and therefore has heat resistance according to the melting point of the plating material. The coating layer 250 formed of a plated metal has higher hardness and heat resistance than a coating layer made of a resin coat.

The vapor chamber 130 in the present embodiment, in which the body section 31 is made of aluminum, which has specific gravity smaller than that of copper, is lighter at least than a vapor chamber made of copper. In addition, using water, the latent heat of vaporization of which is large, as the operating fluid, can provide high cooling performance. Furthermore, the operating fluid formed of water does not cause an adverse effect on the environment, such as the greenhouse effect, unlike chlorofluorocarbon.

In the vapor chamber 130 in the present embodiment, the plated layer that forms the coating layer 250 is made of a metal having an ionization tendency smaller than that of hydrogen. Metals having an ionization tendency smaller than that of hydrogen do not react with the hydrogen ions of the water, which is the operating fluid L. The problem of a decrease in the strength of the aluminum of which the body section 31 is made due to corrosion can therefore be suppressed. Furthermore, since non-condensable hydrogen gas is not produced in the housing compartment SP, the decrease in cooling performance due to the hydrogen gas production can be suppressed.

The vapor chamber 130 in the present embodiment therefore allows reduction in weight of the entire apparatus, and suppression of the hydrogen gas production even when water is used as the operating fluid. That is, the vapor chamber 130 in the present embodiment can provide a heat diffuser that achieves both weight reduction and improved cooling efficiency.

### Fourth Variation

In the vapor chamber 130 in the second embodiment, the coating layer 250 is formed of a monolayer plated layer, and the coating layer may instead have a multilayer structure in which a plurality of plated layers are laminated on each other. A coating layer having the multilayer structure will be described below as a fourth variation.

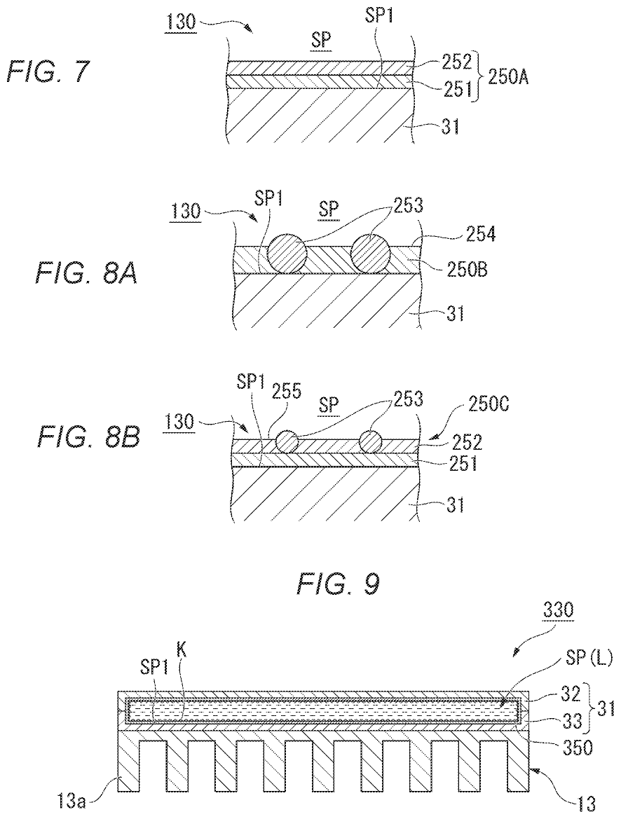

FIG. 7 is a cross-sectional view showing a schematic configuration of a coating layer 250A according to the fourth variation.

The coating layer 250A in the present variation has a laminated structure including a first plated layer 251, which is provided at the inner surface SP1 of the housing compartment SP, and a second plated layer 252, which is laminated on the first plated layer 251 and forms the outermost layer in contact with the operating fluid L, as shown in FIG. 7. The first plated layer 251 and the second plated layer 252 may be made of the same metal material or different metal materials.

In the present embodiment, the first plated layer 251 and the second plated layer 252 are made of different metal materials. The first plated layer 251 is formed of a plated layer made of a metal having an ionization tendency greater than that of hydrogen, and the second plated layer 252 is formed of a plated layer made of a metal having an ionization tendency smaller than that of hydrogen. For example, the first plated layer 251 that forms the inner-side layer of the coating layer 250A is formed with a plated layer made of nickel having an ionization tendency greater than that of hydrogen, and the second plated layer 252 that forms the outermost layer of the coating layer 250A is formed of a plated layer made of gold having an ionization tendency smaller than that of hydrogen.

In the present variation, the second plated layer 252 in contact with the operating fluid L is made of a metal having a small ionization tendency and therefore does not produce hydrogen gas. Therefore, the first plated layer 251 made of nickel, which is a metal having a large ionization tendency, can be used as the ground layer under the second plated layer 252, and can suppress the hydrogen gas production.

For example, the first plated layer 251 is formed as a ground layer by electroless plating, and gold, which forms the second plated layer 252, can then be plated by electrolytic plating. In this case, nickel, which is less expensive than gold, is plated to form the ground layer, and gold is then plated by electrolytic plating to form a thin second plated layer 252 as the outermost layer of the coating layer 250A.

As described above, according to the present variation, in which the coating layer 250A has a two-layer structure, a coating layer 250A having a sufficient film thickness can be formed with the amount of plated gold reduced for cost reduction as compared with a case where the coating layer 250A is entirely formed of plated gold.

The number of laminated plated layers in the coating layer 250A is not limited to a specific number, and three or more plated layers may be laminated on each other. That is, the first plated layer 251 and the second plated layer 252 may sandwich another plated layer.

### Fifth Variation

In the vapor chamber 130 in the second embodiment, a plurality of metal particles may be incorporated in any of the plated layers that form the coating layer 250. A coating layer in which a plurality of metal particles are incorporated in a plated layer will be described below as a fifth variation.

FIG. 8A is a cross-sectional view showing a schematic configuration of a coating layer 250B according to the fifth variation.

A plurality of particles 253 are incorporated in the coating layer 250B according to the present variation, as shown in FIG. 8A. The plurality of particles 253 are, for example, metal oxide particles. In the present embodiment, the plurality of particles 253 are titania particles, that is, titanium oxide particles. The particle diameter of the plurality of particles 253 is greater than the thickness of the coating layer 250B.

The plurality of particles 253 are provided so as to be exposed via a surface 254 of the coating layer 250B. The plurality of particles 253 can therefore produce a capillary force in the coating layer 250B. That is, the coating layer 250B according to the present variation, which satisfactorily holds the water, which is the operating fluid, with the aid of the capillary force, can along with the wick structure K shown in FIG. 3 or in place of the wick structure K facilitate circulation of the operating fluid in the housing compartment SP.

Furthermore, in the present variation, the titania particles, which form the plurality of particles 253, form a passive coating at the surface of the coating layer 250B and can therefore provide a self-repairing function of repairing scratches produced at the surface 254 of the coating layer 250B. That is, the coating layer 250B according to the present variation, which can self-repair scratches produced at the surface 254, can further enhance the corrosion suppression function by suppressing exposure of the aluminum surface of the body section 31 triggered by the scratches produced at the surface 254. The coating layer 250B according to the present variation, in which the inner surface SP1 of the housing compartment SP is stably covered for a long period of time, can therefore provide a vapor chamber 130 that excels in durability.

### Sixth Variation

The coating layer 250B according to the fifth variation has been described with reference to the case where the coating layer 250B has the monolayer structure, and the coating layer 250B may instead have a multilayer structure, such as that in the fourth variation described above. A case where metal particles are incorporated in a coating layer having a multilayer structure will be described below as a sixth variation.

FIG. 8B is a cross-sectional view showing a schematic configuration of a coating layer 250C according to the sixth variation.

A plurality of particles 253 are incorporated in the coating layer 250C, as shown in FIG. 8B. The plurality of particles 253 are incorporated in the second plated layer 252, which forms the outermost layer of the coating layer 250C. The particle diameter of the plurality of particles 253 is greater than the thickness of the second plated layer 252 and are therefore provided so as to be exposed via the surface of the coating layer 250C, that is, a surface 255 of the second plated layer 252.

The coating layer 250C according to the present variation employs a laminated structure to reduce the amount of plated gold for cost reduction and incorporates the particles 253 to improve durability through the self-repairing function and improve the cooling performance with the aid of the produced capillary force. Such an advantageous vapor chamber 130 can thus be provided.

The number of plated layers in the coating layer 250C described above is not limited to two, and three or more plated layers may be laminated on each other.

### Third Embodiment

The vapor chamber according to a third embodiment will be subsequently described. The difference between the present embodiment and the first embodiment is that the coating layer in the vapor chamber is formed of a glass coating in place of the resin coating. In the following description, configurations and members common to those in the first embodiment have the same reference characters and will not be described in detail.

FIG. 9 shows the configurations of key parts of a vapor chamber 330 according to the third embodiment.

The vapor chamber 330 in the present embodiment includes a coating layer 350, which covers the inner surface SP1 of the housing compartment SP of the body section 31 made of aluminum having specific gravity smaller than that of copper, as shown in FIG. 9. The coating layer 350 in the present embodiment is formed of a glass coating containing silicon dioxide.

The vapor chamber 330 in the present embodiment is used to cool, for example, the first light source 41 of the light source apparatus 2, as in the first embodiment.

The coating layer 350 in the present embodiment is formed, for example, of a glass coating film produced by applying a glassy glaze primarily containing silicon dioxide heated to a high temperature onto the inner surface SP1 of the housing compartment SP.

In the vapor chamber 330 in the present embodiment, the coating layer 350 is formed of a glass coating and therefore has heat resistance corresponding to the melting point of glass and hardness comparable to that of glass.

The vapor chamber 330 in the present embodiment, in which the body section 31 is made of aluminum, which has specific gravity smaller than that of copper, is lighter at least than a vapor chamber made of copper. In addition, using water, the latent heat of vaporization of which is large, as the operating fluid, can provide high cooling performance. Furthermore, the operating fluid formed of water does not cause an adverse effect on the environment, such as the greenhouse effect, unlike chlorofluorocarbon.

Since the vapor chamber 330 in the present embodiment includes the coating layer 350 formed of a glass coating that excels in heat resistance and has high hardness that provides scratch resistance, the problem of a decrease in the strength of the aluminum of which the body section 31 is made due to corrosion can be suppressed. Furthermore, since non-condensable hydrogen gas is not produced in the housing compartment SP, the decrease in cooling performance due to the hydrogen gas production can be suppressed.

In the present embodiment, the case where the body section 31 is made of aluminum is presented by way of example, and aforementioned SUS, titanium, and magnesium, and other metal materials having specific gravity smaller than that of copper have an ionization tendency greater than that of hydrogen as aluminum does, and can therefore undesirably produce hydrogen gas when the operating fluid is water. Therefore, when the body section 31 is made of SUS, titanium, or magnesium, which has specific gravity smaller than that of copper, providing the coating layer 350 can similarly suppress the hydrogen gas production.

The vapor chamber 330 in the present embodiment therefore allows reduction in weight of the entire apparatus, and suppression of the hydrogen gas production even when water is used as the operating fluid. That is, the vapor chamber 330 in the present embodiment can provide a heat diffuser that achieves both weight reduction and improved cooling efficiency.

The coating layer 350 may instead have a laminated structure in which a plurality of glass coating films are laminated on each other. According to the configuration described above, the glass coating films can be separately formed in a plurality of steps to form a uniform, thick coating layer 350.

### Fourth Embodiment

The vapor chamber according to a fourth embodiment will be subsequently described. The present embodiment differs from the first embodiment in that the heat dissipater of the vapor chamber also serves as the heat dissipating member. In the following description, configurations and members common to those in the first embodiment have the same reference characters and will not be described in detail.

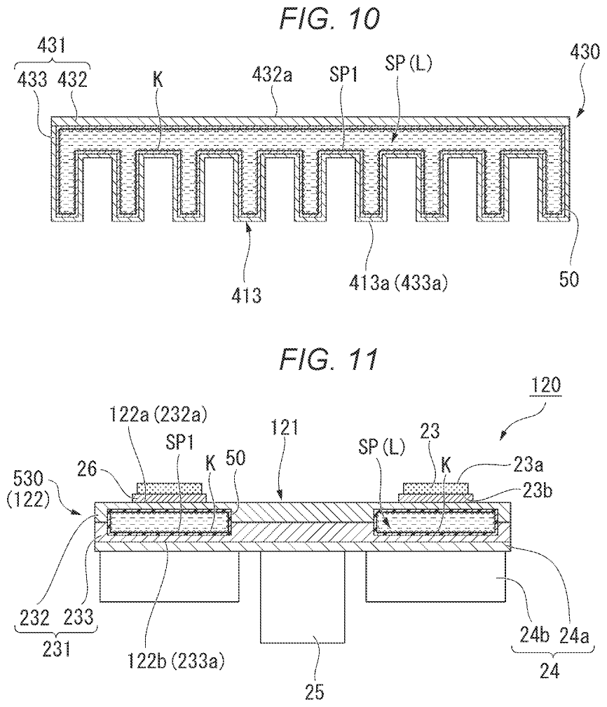

FIG. 10 shows the configurations of key parts of a vapor chamber 430 according to the fourth embodiment.

The vapor chamber 430 according to the present embodiment includes a body section 431 formed of the combination of a heat receiving plate 432 and a heat dissipating plate 433, as shown in FIG. 10. The body section 431 is made of aluminum, which has specific gravity smaller than that of copper, and the inner surface SP1 of the housing compartment SP is covered with the coating layer 50.

In the present embodiment, the surface of the heat dissipating plate 433 forms a plurality of heat dissipating fins 413a, which form a heat dissipating member 413. That is, in the present embodiment, the surfaces of the heat dissipating fins 413a form a heat dissipater 433a of the vapor chamber 430, and the housing compartment SP is provided in each of the heat dissipating fins 413a.

According to the vapor chamber 430 in the present embodiment, the heat dissipater 433a forms the shapes of the surfaces of the heat dissipating fins 413a of the heat dissipating member 413, whereby the area where the heat dissipater 433a is in contact with the outside air can be increased. The vapor chamber 430 thus efficiently dissipates the heat received by a heat receiver 432a, whereby the cooling efficiency can be further improved.

### Fifth Embodiment

A light source apparatus according to a fifth embodiment of the present disclosure will be subsequently described. In the light source apparatus 2 according to the embodiment described above, the case where the vapor chamber is used as a heat diffuser that cools the first light source 41, which is the excitation light source, is presented by way of example, but the application of the heat diffuser according to the present disclosure is not limited thereto. The light source apparatus according to the present embodiment includes a vapor chamber as a heat diffuser that cools the phosphor wheel of the wavelength converter. In the following description, configurations and members common to those in the embodiments described above have the same reference characters and will not be described in detail.

FIG. 11 is a cross-sectional view showing the configurations of key parts of a wavelength converter 120 according to the fifth embodiment.

The wavelength converter 120 according to the present embodiment includes a phosphor wheel 121, the rotation driver 25, and a vapor-chamber-type heat diffuser 530, which is the heat diffuser, as shown in FIG. 11. The phosphor wheel 121 includes a wheel substrate 122, the phosphor 23, and the heat dissipating member 24.

The vapor chamber 530 includes a disc-shaped body section 231 formed of the combination of a heat receiving plate 232 and a heat dissipating plate 233. The heat receiving plate 232 and the heat dissipating plate 233, which form the body section 231, are made of a metal material having specific gravity smaller than that of copper.

The housing compartment SP, which houses and seals water as the operating fluid, is provided in the body section 231, and the aforementioned coating layer 50 formed of a resin coat is provided at the inner surface SP1 of the housing compartment SP. In the present embodiment, the housing compartment SP is provided in correspondence with the phosphor 23, which is the cooling target. That is, the housing compartment SP has an annular planar shape, as the phosphor 23 does.

The vapor chamber 530 in the present embodiment is integrated with the wheel substrate 122. A first surface 122a of the wheel substrate 122, the surface at which the phosphor 23 is provided, is the surface of the heat receiving plate 232. A second surface 122b of the wheel substrate 122, the surface at which the heat dissipation member 24 is provided, is the surface of the heat dissipating plate 233. The reflection member 26 is provided between the rear surface 23b of the phosphor 23 and the first surface 122a of the wheel substrate 122.

In the present embodiment, the heat of the phosphor 23 is transferred to the first surface 122a of the wheel substrate 122. That is, the heat of the phosphor 23 is transferred to a heat receiver 232a provided at the surface of the heat receiving plate 232 of the vapor chamber 530. The heat receiver 232a vaporizes the water, which is the operating fluid, into water vapor with the aid of the heat from the phosphor 23.

The water vapor vaporized by the heat receiver 232a moves toward the second surface 122b of the wheel substrate 122. That is, the heat of the water vapor is dissipated via the heat dissipater 233a, which is provided at the surface of the heat dissipating plate 233 of the vapor chamber 530, so that the dissipated water vapor is condensed back into water.

As described above, the vapor chamber 530 in the present embodiment, which diffuses the heat of the phosphor 23 from the heat receiver 232a to the heat dissipater 233a, can efficiently cool the phosphor 23 of the phosphor wheel 121.

The vapor chamber 530 in the present embodiment, in which the inner surface SP1 of the housing compartment SP, which is provided in the body section 231 made of aluminum, is covered with the coating layer 50, can use water as the operating fluid while suppressing the hydrogen gas production. The vapor chamber 530 in the present embodiment is therefore lightweight and excels in cooling efficiency.

The wavelength converter 120 according to the present embodiment, in which the vapor chamber 530 integrated with the wheel substrate 122 is lightweight, allows reduction in size of the rotation driver 25 itself, which rotates the wheel substrate 122.

The wavelength converter 120 according to the present embodiment, in which the vapor chamber 530 efficiently cools the phosphor 23, can suppress a decrease in fluorescence conversion efficiency due to an increase in temperature of the phosphor 23. The light source apparatus according to the present embodiment using the wavelength converter 120 can therefore generate the illumination light WL containing the bright fluorescence Y.

In the present embodiment, the case where the body section 231 is made of aluminum is presented by way of example, and aforementioned SUS, titanium, and magnesium, and other metal materials having specific gravity smaller than that of copper have an ionization tendency greater than that of hydrogen as aluminum does, and can therefore undesirably produce hydrogen gas when the operating fluid is water. Therefore, when the body section 231 is made of SUS, titanium, or magnesium, which has specific gravity smaller than that of copper, providing the coating layer 50 can similarly suppress the hydrogen gas production.

The inner surface SP1 of the housing compartment SP may not be covered with the coating layer 50 and may instead be covered with any of the coating layers 50A, 50B, 50C, 250, 250A, 250B, and 250C in the embodiments and variations described above. In this case, the hydrogen gas production can still be suppressed.

### Seventh Variation

In the wavelength converter 120 according to the fifth embodiment, the vapor chamber 530 and the wheel substrate 122 are integrated with each other, and the vapor chamber 530 and the wheel substrate 122 may instead be formed separately from each other. A wavelength converter formed of a vapor chamber and a wheel substrate formed separately from each other will be described below as a seventh variation.

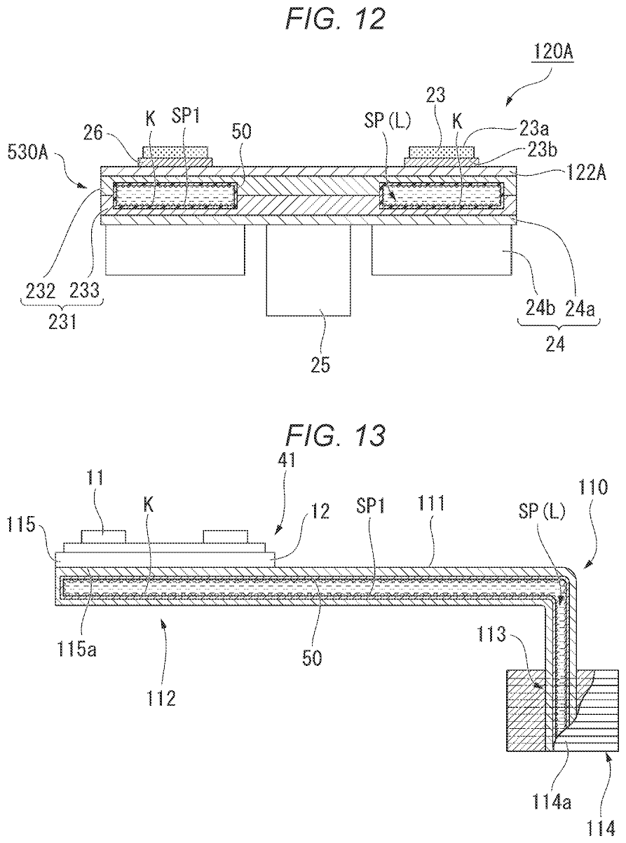

FIG. 12 is a cross-sectional view showing the configurations of key parts of the wavelength converter according to the seventh variation. In a wavelength converter 120A according to the present variation, a vapor chamber 530A may be provided between a wheel substrate 122A and the heat dissipating member 24, as shown in FIG. 12. According to the configuration described above, in which the wheel substrate 122A and the heat dissipating member 24 are bonded to the opposite surfaces of the vapor chamber 530A, the wavelength converter 120A can be readily assembled.

### Sixth Embodiment

A light source apparatus according to a sixth embodiment of the present disclosure will be subsequently described. In the embodiments described above, the case where a vapor chamber is used as the heat diffuser is presented by way of example, and a heat pipe can also be used as the heat diffuser according to the present disclosure. The heat pipe in the present embodiment can replaced with, for example, the vapor chamber 30 of the first light source 41 in the first embodiment. In the following description, configurations and members common to those in the embodiments described above have the same reference characters and will not be described in detail.

FIG. 13 is a cross-sectional view showing a schematic configuration of a heat pipe in the sixth embodiment.

A heat-pipe-type heat diffuser 110, which is the heat diffuser, is used to cool the first light source 41, as shown in FIG. 13. The heat pipe 110 includes a body section 111, which extends as a pipe does, a heat receiver 112, which is provided at one end of the body section 111, a heat dissipater 113, which is provided at the other end of the body section 111, and a heat dissipating member 114, which is provided at the heat dissipater 113. The heat dissipating member 114 is a heat sink including a plurality of heat dissipating fins 114a.

In the present embodiment, the body section 111 is made of a metal material having specific gravity smaller than that of copper, for example, aluminum.

The housing compartment SP, which houses and seals water, which is the operating fluid L, is provided in the body section 111. In the heat pipe 110 in the present embodiment, the inner surface SP1 of the housing compartment SP is covered with the coating layer 50.

The heat receiver 112 of the heat pipe 110 is thermally coupled to a support member 115, which supports the mounting substrate 12 of the first light source 41. The support member 115 is formed of a plate made of a metal that excels in heat dissipation, for example, aluminum or copper. Specifically, the heat receiver 112 of the heat pipe 110 is thermally coupled to a surface 115a of the support member 115, the surface opposite from the mounting substrate 12.

The heat pipe 110 in the present embodiment, in which the body section 111 is made of aluminum, which has specific gravity smaller than that of copper, is lighter at least than a heat pipe made of copper. In addition, using water, the latent heat of vaporization of which is large, as the operating fluid L, can provide high cooling performance. Furthermore, the operating fluid L formed of water does not cause an adverse effect on the environment, such as the greenhouse effect, unlike chlorofluorocarbon.

In the present embodiment, the inner surface SP1 of the housing compartment SP is covered with the coating layer 50, so that the water housed in the housing compartment SP is not in direct contact with the aluminum of which the housing compartment SP is made, whereby the hydrogen gas production in the housing compartment SP can be suppressed. The problem of a decrease in the strength of the aluminum of which the body section 111 is made due to corrosion can therefore be suppressed. Furthermore, since non-condensable hydrogen gas is not produced in the housing compartment SP, the decrease in cooling performance due to the hydrogen gas production can be suppressed.

In the present embodiment, the case where the body section 111 is made of aluminum is presented by way of example, and aforementioned SUS, titanium, and magnesium, and other metal materials having specific gravity smaller than that of copper have an ionization tendency greater than that of hydrogen as aluminum does, and can therefore undesirably produce hydrogen gas when the operating fluid is water. Therefore, when the body section 111 is made of SUS, titanium, or magnesium, which has specific gravity smaller than that of copper, providing the coating layer 50 can similarly suppress the hydrogen gas production.

The heat pipe 110 in the present embodiment therefore allows suppression of the hydrogen gas production even when the body section 111 is made of a metal material having specific gravity smaller than that of copper to reduce the weight of the entire apparatus, and when water is used as the operating fluid. That is, the heat pipe 110 in the present embodiment provides a heat diffuser that excels in weight reduction and cooling efficiency.

The weight of the light source apparatus using the heat pipe 110 in the present embodiment can therefore also be reduced, whereby an increase in the weight of the projector itself, which incorporates the light source apparatus, can be suppressed.

The inner surface SP1 of the housing compartment SP may not be covered with the coating layer 50 and may instead be covered with any of the coating layers 50A, 50B, 50C, 250, 250A, 250B, and 250C in the embodiments and variations described above. In this case, the hydrogen gas production can still be suppressed.

The technical scope of the present disclosure is not limited to the embodiments described above, and a variety of changes can be made thereto to the extent that the changes do not depart from the substance of the present disclosure.

In addition to the above, the number, arrangement, shape, material, and other specific factors of the variety of components that form the light source apparatus are not limited to those in the embodiments described above and can be changed as appropriate.

For example, a glass component may be added to the interior of the coating layer 50 formed of the resin coat in the first embodiment. According to the configuration described above, the durability and heat resistance of the coating layer 50 can be improved by the incorporated glass component.

The coating layer 50B in the second variation, the coating layer 50C in the third variation, the coating layer 250B in the fifth variation, and the coating layer 250C in the sixth variation have been described with reference to the case where titania particles are incorporated in the coating layers, and glass particles may be incorporated in the coating layers in place of the titania particles.

In the light source apparatus 2 according to the embodiments described above, the heat dissipating member 13 for the first light source 41 has an air cooled structure in which the plurality of heat dissipating fins 13a are cooled by air, but the configuration of the heat dissipating member is not limited thereto. The heat dissipating member may, for example, have a liquid cooled structure in which the operating fluid such as water is supplied to the spaces between the plurality of heat dissipating fins 13a via pipe members to cool the fins.

Applications of the heat diffuser are not limited to those described in the embodiments and variations described above. For example, the heat pipe in the fifth embodiment may be used to cool the battery of an electric vehicle. The heat pipe is lightweight and excels in cooling performance and can therefore suppress an increase in the weight of the vehicle body that incorporates the heat pipe to improve the fuel efficiency of the automobile.

In the embodiments described above, the projector 1 including the three light modulators 4R, 4G, and 4B has been presented by way of example, and the present disclosure is also applicable to a projector that displays color video images via one light modulator. Furthermore, the light modulators are not limited to the liquid crystal panels described above and can instead, for example, be digital mirror devices.

In the embodiments described above, the light source apparatus according to the present disclosure is used in a projector by way of example, but not necessarily. The light source apparatus according to the present disclosure may be used as a lighting apparatus, such as a headlight of an automobile.

A heat diffuser according to an aspect of the present disclosure may have the configuration below.

A heat diffuser according to an aspect of the present disclosure includes a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than that of copper. The inner surface of the housing compartment is covered with a coating layer. The coating layer is a resin coat containing any of the following resins: alkyd resin; silicone resin; ethylene-chlorotrifluoroethylene copolymer resin; and tetrafluoroethylene-perfluoro alkyl vinyl ether copolymer resin. The heat from the heat receiver vaporizes the operating fluid in the liquid form, and the heat dissipation performed by the heat dissipater condenses the operating fluid.

In the heat diffuser according to the aspect described above, the silicone resin may be any of pure silicone resin, modified silicone resin, and inorganic-filler-added silicone resin.

In the heat diffuser according to the aspect described above, the silicone resin may contain a metal oxide.

In the heat diffuser according to the aspect described above, the coating layer may have a multilayer structure in which a plurality of resin coats are laminated on each other.

In the heat diffuser according to the aspect described above, the coating layer may incorporate a plurality of particles, and the plurality of particles may be so provided as to be exposed via the surface of the coating layer and produce a capillary force in the coating layer.

In the heat diffuser according to the aspect described above, the plurality of particles may be titania particles.

A heat diffuser according to another aspect of the present disclosure may have the configuration below.

A heat diffuser according to another aspect of the present disclosure includes a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than that of copper. The inner surface of the housing compartment is covered with a coating layer. At least the surface of the coating layer is formed of a plated layer made of a metal having an ionization tendency smaller than that of hydrogen. The heat from the heat receiver vaporizes the operating fluid in the liquid form, and the heat dissipation performed by the heat dissipater condenses the operating fluid.

In the heat diffuser according to the aspect described above, the coating layer may have a multilayer structure in which a plurality of plated layers are laminated on each other.

In the heat diffuser according to the aspect described above, the coating layer may include a first plated layer provided at the inner surface of the housing compartment and a second plated layer that is laminated on the first plated layer and forms the outermost layer in contact with the operating fluid. The first plated layer may be formed of a plated layer made of a metal having an ionization tendency greater than that of hydrogen, and the second first plated layer may be formed of a plated layer made of a metal having an ionization tendency smaller than that of hydrogen.

In the heat diffuser according to the aspect described above, the coating layer may incorporate a plurality of particles, and the plurality of particles may be so provided as to be exposed via the surface of the coating layer and produce a capillary force in the coating layer.

A heat diffuser according to another aspect of the present disclosure may have the configuration below.

A heat diffuser according to another aspect of the present disclosure includes a body section including a heat receiver that receives heat from a heat source, a heat dissipater that dissipates the heat received by the heat receiver, and a housing compartment that houses and seals an operating fluid. The operating fluid is water. The housing compartment is made of a metal material having specific gravity smaller than that of copper. The inner surface of the housing compartment is covered with a coating layer. The coating layer is a glass coating containing silicon dioxide. The heat from the heat receiver vaporizes the operating fluid in the liquid form, and the heat dissipation performed by the heat dissipater condenses the operating fluid.

A wavelength conversion apparatus according to another aspect of the present disclosure may have the configuration below.

A wavelength converter according to another aspect of the present disclosure includes a phosphor wheel including a wheel substrate, a phosphor provided at a first surface of the wheel substrate, and a heat dissipating member provided at a second surface of the wheel substrate, the surface opposite from the first surface, and a vapor chamber that is formed of the heat diffuser described above and cools the phosphor, and the vapor chamber is so provided as to be integrated with the wheel substrate or provided between the wheel substrate and the heat dissipating member.

A light source apparatus according to another aspect of the present disclosure may have the configuration below.

A light source apparatus according to another aspect of the present disclosure includes a light source and a vapor chamber that cools the light source, and the vapor chamber is the heat diffuser according to the aspect described above.

In the light source apparatus according to the aspect described above, the light source may include a light emitter that outputs light and a mounting substrate at which the light emitter is mounted, and the mounting substrate of the light source may be provided at the light receiver of the vapor chamber.

In the light source apparatus according to the aspect described above, the surface of the heat dissipater of the vapor chamber may form a plurality of heat dissipating fins.

A light source apparatus according to another aspect of the present disclosure may have the configuration below.

A light source apparatus according to another aspect of the present disclosure includes a light source and a heat pipe that cools the light source, and the heat pipe is the heat diffuser according to the aspect described above.

In the light source apparatus according to the aspect described above, the light source may include a light emitter that outputs light, a mounting substrate at which the light emitter is mounted, and a support member that supports the mounting substrate, and the heat receiver of the heat pipe may be coupled to the support member, which supports the mounting substrate of the light source.

A light source apparatus according to another aspect of the present disclosure may have the configuration below.

A light source apparatus according to another aspect of the present disclosure includes the wavelength converter according to the aspect described above and a light source that outputs excitation light to the phosphor wheel of the wavelength converter.

A projector according to another aspect of the present disclosure may have the configuration below.

A projector according to another aspect of the present disclosure includes the light source apparatus according to the aspect described above, a light modulator that modulates the light from the light source apparatus in accordance with image information to form image light, and a projection optical apparatus that projects the image light.

What is claimed is:

1. A heat diffuser comprising:
a body section including a heat receiver that receives heat from a heat source;
a heat dissipater that dissipates the heat received by the heat receiver; and
a housing compartment that houses and seals an operating fluid,
wherein the operating fluid is water,
the housing compartment is made of a metal material having specific gravity smaller than specific gravity of copper,
an inner surface of the housing compartment is covered with a coating layer,
the coating layer is a resin coat containing any of alkyd resin, silicone resin, ethylene-chlorotrifluoroethylene copolymer resin, and tetrafluoroethylene-perfluoro alkyl vinyl ether copolymer resin, and
the heat from the heat receiver vaporizes the operating fluid in a liquid form, and the heat dissipation performed by the heat dissipater condenses the operating fluid.

2. The heat diffuser according to claim 1,
wherein the silicone resin is any of pure silicone resin, modified silicone resin, and inorganic-filler-added silicone resin.

3. The heat diffuser according to claim 2,
wherein the silicone resin contains a metal oxide.

4. The heat diffuser according to claim 1,
wherein the coating layer has a multilayer structure in which a plurality of the resin coats are laminated on each other.

5. The heat diffuser according to claim 1,
wherein the coating layer incorporates a plurality of particles, and
the plurality of particles are so provided as to be exposed via a surface of the coating layer and produce a capillary force in the coating layer.

6. The heat diffuser according to claim 5,
wherein the plurality of particles are titania particles.

7. A heat diffuser comprising:
a body section including a heat receiver that receives heat from a heat source;
a heat dissipater that dissipates the heat received by the heat receiver; and
a housing compartment that houses and seals an operating fluid,
wherein the operating fluid is water,
the housing compartment is made of a metal material having specific gravity smaller than specific gravity of copper,
an inner surface of the housing compartment is covered with a coating layer,
at least a surface of the coating layer is formed of a plated layer made of a metal having an ionization tendency smaller than an ionization tendency of hydrogen, and
the heat from the heat receiver vaporizes the operating fluid in a liquid form, and the heat dissipation performed by the heat dissipater condenses the operating fluid.

8. The heat diffuser according to claim 7,
wherein the coating layer has a multilayer structure in which a plurality of the plated layers are laminated on each other.

9. The heat diffuser according to claim 8,
wherein the coating layer includes a first plated layer provided at the inner surface of the housing compartment and a second plated layer that is laminated on the first plated layer and forms an outermost layer in contact with the operating fluid,
the first plated layer is formed of a plated layer made of a metal having an ionization tendency greater than an ionization tendency of hydrogen, and
the second plated layer is formed of a plated layer made of a metal having an ionization tendency smaller than the ionization tendency of hydrogen.

10. The heat diffuser according to claim 7,
wherein the coating layer incorporates a plurality of particles, and
the plurality of particles are so provided as to be exposed via a surface of the coating layer and produce a capillary force in the coating layer.

11. A heat diffuser comprising:
a body section including a heat receiver that receives heat from a heat source;
a heat dissipater that dissipates the heat received by the heat receiver; and
a housing compartment that houses and seals an operating fluid,
wherein the operating fluid is water,
the housing compartment is made of a metal material having specific gravity smaller than specific gravity of copper,
an inner surface of the housing compartment is covered with a coating layer,
the coating layer is a glass coating containing silicon dioxide, and
the heat from the heat receiver vaporizes the operating fluid in a liquid form, and the heat dissipation performed by the heat dissipater condenses the operating fluid.

12. A wavelength converter comprising:
a phosphor wheel including a wheel substrate, a phosphor provided at a first surface of the wheel substrate, and a heat dissipating member provided at a second surface of the wheel substrate, the surface opposite from the first surface; and
a vapor chamber that is formed of the heat diffuser according to claim 1 and cools the phosphor,
wherein the vapor chamber is so provided as to be integrated with the wheel substrate or provided between the wheel substrate and the heat dissipating member.

13. A light source apparatus comprising:
a light source; and
a vapor chamber that cools the light source,
wherein the vapor chamber is the heat diffuser according to claim 1.

14. The light source apparatus according to claim 13,
wherein the light source includes a light emitter that outputs light and a mounting substrate at which the light emitter is mounted, and
the mounting substrate of the light source is provided at the light receiver of the vapor chamber.

15. The light source apparatus according to claim 14,
wherein a surface of the heat dissipater of the vapor chamber forms a plurality of heat dissipating fins.

16. A light source apparatus comprising:
a light source; and
a heat pipe that cools the light source,
wherein the heat pipe is the heat diffuser according to claim 1.

17. The light source apparatus according to claim 16,
wherein the light source includes a light emitter that outputs light, a mounting substrate at which the light emitter is mounted, and a support member that supports the mounting substrate, and
the heat receiver of the heat pipe is coupled to the support member of the light source.

18. A light source apparatus comprising:
the wavelength converter according to claim 12; and
a light source that outputs excitation light to the phosphor wheel of the wavelength converter.

19. A projector comprising:
the light source apparatus according to claim 13;
a light modulator that modulates light from the light source apparatus in accordance with image information to form image light; and
a projection optical apparatus that projects the image light.
